(19) United States
(12) Patent Application Publication
(10) Pub. No.: US 2011/0006362 A1
(43) Pub. Date: Jan. 13, 2011

(54) Trench MOSFET with on-resistance reduction

(75) Inventor: Fu-Yuan Hsieh, Kaohsiung (TW)

Correspondence Address: BACON & THOMAS, PLLC, 625 SLATERS LANE, FOURTH FLOOR, ALEXANDRIA, VA, 22314-1176, US

(73) Assignee: FORCE MOS TECHNOLOGY CO. LTD., Kaohsiung (TW)

(21) Appl. No.: 12/458,400

(22) Filed: Jul. 10, 2009

(51) Int. Cl. H01L 29/78; H01L 21/336

(52) U.S. Cl. 257/330; 438/270; 257/342; 257/E29.262; 257/E21.41; 257/E21.214

(57) ABSTRACT

A trench MOSFET with on-resistance reduction comprises a trenched gate surrounded by a source region encompassed in a body region above a drain region disposed on a bottom surface of a substrate, wherein the said MOSFET further comprises a plurality of source-body contact trenches opened relative to a top surface into said source and body regions and each of the source-body contact trenches is filled with a contact metal plug as a source-body contact; a insulation layer covered over the top of the trenched gate, the body region and the source region; a front metal layer formed on a top surface of the MOSFET; wherein a low-resistivity phosphorus substrate and retrograded P-body formed by medium or high energy Ion Implantation to reduce Rds contribution from substrate and drift region.

### BACKGROUND OF THE INVENTION

1. Field of the Invention

This invention relates generally to the cell structure and fabrication process of power semiconductor devices. More particularly, this invention relates to a novel and improved cell structure and improved process of fabricating a trenched semiconductor power device with reduced drain-source resistance and better metal step coverage.

2. The Prior Arts

Conventional technologies of forming aluminum metal contact to the N+ source and P-well formed in the P-body regions in a semiconductor device is encountering a technical difficulty of poor metal coverage and unreliable electrical contact when the cell pitch is shrunken. The technical difficulty is especially pronounced when a metal oxide semiconductor field effect transistor (MOSFET) cell density is increased above 200 million cells per square inch (200 M/in2) with the cell pitch reduced to 1.8 um or to even a smaller dimension. The metal contact space to both N+ source and P-well in the P-body regions for cell density higher than 200 M/in2 is less than 1.0 um, resulting in poor metal step coverage and high contact resistance to both N+ and P-body region. The device performance is adversely affected by these poor contacts and the product reliability is also degraded.

In U.S. Pat. No. 6,888,196, a vertical MOSFET with source body contact was disclosed, as shown in FIG. 1. In FIG. 1, a metal oxide semiconductor field effect transistor (MOSFET) device is supported on a N+ Arsenic substrate 1 formed with an N− epitaxial layer 2. The MOSFET device includes a trenched gate 8 disposed in a trench with a gate insulation layer 6 formed over the walls of the trench. A body region 9 that is doped with a dopant of second conductivity type, e.g., P-type dopant, extends between the trenched gates 8. On the polysilicon 8 to serve as a gate electrode or a trench gate, an interlayer oxide 15 is formed. The P-body regions 9 encompassing a source region 10 doped with the dopant of first conductivity, e.g., N+ dopant. The source regions 10 are formed near the top surface of the epitaxial layer surrounding the trenched gates 8. The unit cell have a contact hole 12 formed on a center of the surface of epitaxial layer and extending from the surface of epitaxial layer through the source layer to an inside of the P-body region 9, a tungsten contact 7 is filled in the contact hole. A layer of Al alloys 16 is formed on the contact. The unit cell further comprises a P+ region 14 within the P-body region 9 so as to enclose a bottom of the contact and to bring the P-body region 9 into contact with the bottom of the contact.

Referring to FIG. 2, a curve 1001 is concentration distribution of a P-body formed by ion implantation at low energy, a curve 1002 is concentration distribution of an epitaxial layer on an Arsenic substrate, and a curve 1003 is concentration distribution of an epitaxial layer on a Phosphorus substrate. Considering the Arsenic substrate, which has a typical resistivity of 2.5 mohm-cm, the substrate resistance is significantly contributed to Rds. If use Phosphorus substrate with a typical resistivity of 1.2 mohm-cm to take the place of Arsenic substrate, incorporated with the low energy Ion Implantation (30˜80 KeV), thicker epitaxial layer is required to maintain targeted BV, as shown in FIG. 2, resulting in less benefit of the use of Phosphorus substrate since drift resistance is higher due to the higher diffusion coefficient and higher doping concentration of Phosphorus than Arsenic, which will lead to longer out diffusion region from phosphorus substrate.

Another limitation of the MOSFET device structure in the prior art is the poor contact resistance which partly caused by the poor contact between W and Al alloys 16. In another respect, considering the trench contact is not stepwise, it offers less contact area between W and Al alloys 16, which causing further poor contact resistance. Both aspects discussed above bring a high drain-source resistance which will lead to a power wastage. Otherwise, the process limitation discussed above is another important aspects to impact drain-source resistance. Therefore, there is still a need in the art of the semiconductor device fabrication, particularly for trenched power MOSFET design and fabrication, to provide a novel transistor structure and fabrication process that would resolve these difficulties and design limitations.

### SUMMARY OF THE INVENTION

It is therefore an object of the present invention to provide new and improved processes to form a more reliable source contact metal layer with smaller CD to allow for higher cell density and to form a structure with improved avalanche capability and reduced contact resistance and source-drain resistance such that the above discussed technical difficulties may be resolved.

Specially, it is an object of the present invention to provide a new and improved cell configuration and fabrication process to form a source metal contact by opening a source-body contact trench by applying an oxide etch followed by a silicon etch. The source-body contact trench then filled with a metal plug to assure reliable source-body contact is established. The source-body contact trench is further using Ti/TiN/W, or Co/TiN/W plug in sloped trench source contact for providing good metal step coverage over contact CD smaller than 1.0 um for achieving higher cell density and drain-source resistance can be also reduced as well as the channel resistance.

Another aspect of the present invention is to further reduce the drain and source resistance significantly by forming P-body with medium or high energy Ion Implantation or combination of both energies Ion Implantation. This method of Ion Implantation at medium or high energy can shorten P-body anneal or diffusion. Incorporating with Phosphorus substrate with resistivity lower than 2.0 mohm-cm, the drain-source resistance is hence reduced significantly. Thus drift resistance and substrate resistance are also reduced.

Another aspect of the present invention is the new metal scheme of Ti/TiN/W/Ti thick front metal or Co/Ti/TiN/W thick front metal due to the use of Ti/TiN or Co/TiN as alternative as barrier layer discussed above which will provide good ohmic contact, and further reduce the contact resistance.

Another aspect of the present invention is the champagne cup shaped contact, which has two advantages. One is the forming the stepwise structure for better ohmic contact, the other is there is no need to etch off Ti/TiN or Co/TiN after the tungsten is etched back which is benefit for the saving of fabricating cost.

Another aspect of the present invention is improved device ruggedness with the sloped source trench contact (60˜90 degree respect to epi surface) and optimum space between trench and contact (0.1˜0.3 um) without impacting drain-source resistance. Because of the P+ region touching channel region, the drain-source resistance is significantly increased if the contact space is smaller than 0.1 um, and if the space is greater than 0.3 um, the avalanche capability is degraded due to a parasitic N+P/N is triggered on. Those two aspects sufficiently indicate the present invention is deserved to be put into application.

Briefly, in a preferred embodiment, the present invention discloses a trenched metal oxide semiconductor field effect transistor (MOSFET) cell that includes a trenched gate surrounded by a source region encompassed in a body region above a drain region disposed on a bottom surface of a Phosphorus substrate with a resistivity lower than 2.0 mohm-cm, and the said P-body region is implanted by using medium or high energy Ion Implantation to assurance the drain-source resistance is reduced. The MOSFET cell further includes a source-body contact trench opened with champagne cup shape and surrounded by a Ti/TiN or Co/TiN as alternative as barrier layer and filled with contact metal plug. A body-resistance reduction region P+ doped with body-doped is formed to surround the source-body contact trench to reduce a body-region resistance between the source-body contact metal and the trenched gate to improve an avalanche capability. In a preferred embodiment, the contact metal plug further comprises a Ti/TiN or Co/TiN barrier layer surrounding a tungsten core as a source-body contact metal. In another preferred embodiment, the MOSFET cell further includes an insulation layer compromising BPSG or PSG and undoped SRO (silicon rich oxide) covering a top surface over the MOSFET cell wherein the source body contact trench is opened through the insulation layer. And, the MOSFET cell further includes a thin resistance-reduction conductive layer such as Ti or Ti/TiN disposed on a top surface covering the insulation layer and contacting the contact metal plug whereby the resistance-reduction conductive layer having a greater area than a top surface of the contact metal plug for reducing a source-body resistance. In another preferred embodiment, the MOSFET cell further includes a thick front metal layer disposed on top of the resistance-reduction layer for providing a contact layer for a wire or wireless bonding package. In another preferred embodiment, the sloped source trench contact has a degree of 60˜90 respect to epi surface and the optimum space between trench and contact is 0.1˜0.3 um, therefore the device ruggedness is improved without impacting drain-source resistance.

This invention further discloses a method for manufacturing a trenched metal oxide semiconductor field effect transistor (MOSFET) cell comprising a step of forming said MOSFET cell with a trenched gate surrounded by a source region encompassed in a body region above a drain region disposed on a bottom surface of a Phosphorus substrate. In a preferred embodiment, the step of implanting the P-body region is a step of Ion Implantation with medium or high energy in a epi formed above the Phosphorus substrate which has a resistivity lower than 2.0 mohm-cm. The method further includes a step of covering the MOSFET cell with an insulation layer and applying a contact mask for opening a source-body contact trench. In a preferred embodiment, the step to form a source-body contact with stepwise sidewalls is applying a wet oxide etch to etch the insulation layer and depositing Ti/TiN or Co/TiN layer and there is or no Ti/TiN or Co/TiN etch off step after the W etch back. The method further includes a step of forming a body-resistance-reduction-dopant region by implanting a body-resistance-reduction-dopant in the body region immediately near the source-body contact trench whereby an avalanche capability of the MOSFET cell is enhanced. In a preferred embodiment, the step of implanting the body-resistance-reduction-dopant is a step of implanting a dopant of a same conductivity type as a body dopant doped in the body region. In a preferred embodiment, the step of forming the body-resistance-reduction region further includes a step of forming the body-resistance-reduction region surrounding a bottom portion of the source-body contact trench.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a conventional MOSFET device.

FIG. 2 is a profile of a MOSFET with Arsenic/Phosphorus substrate with P-body formed with low energy and subsequent anneal at 1150 C.

FIG. 3 is a cross sectional view of a MOSFET device of phosphorus substrate of this invention with an improved source-plug contact disposed in sloped source-body contact trenches and Ti/TiN as barrier layer or Co/TiN as alternative for smaller CD. The Ti/TiN or Co/TiN barrier on the top of the insulator is etched off prior to Ti(or Ti-Rich TiN)/Thick metal deposition.

FIG. 4 is a cross sectional view of a MOSFET device of phosphorus substrate of this invention with an improved source-plug contact disposed in sloped source-body contact trenches and Ti/TiN as barrier layer or Co/TiN as alternative for smaller CD. The Ti/TiN or Co/TiN barrier on the top of the insulator is not etched off prior to Ti(or Ti/TiN)/Thick metal deposition.

FIG. 5 is a cross sectional view of a MOSFET device of this invention to show how it works to improve avalanche capability.

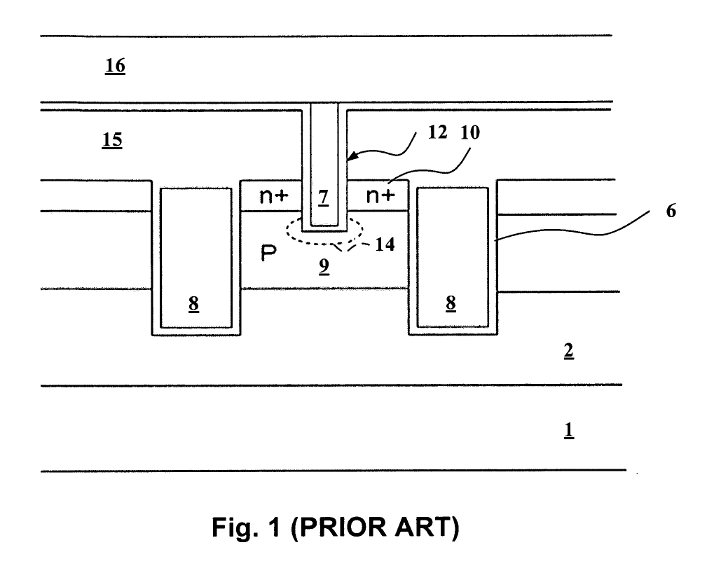

### DETAILED DESCRIPTION OF THE EMBODIMENTS

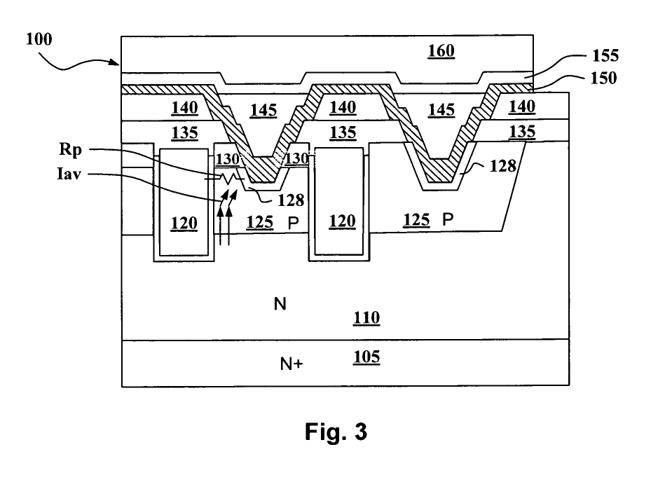

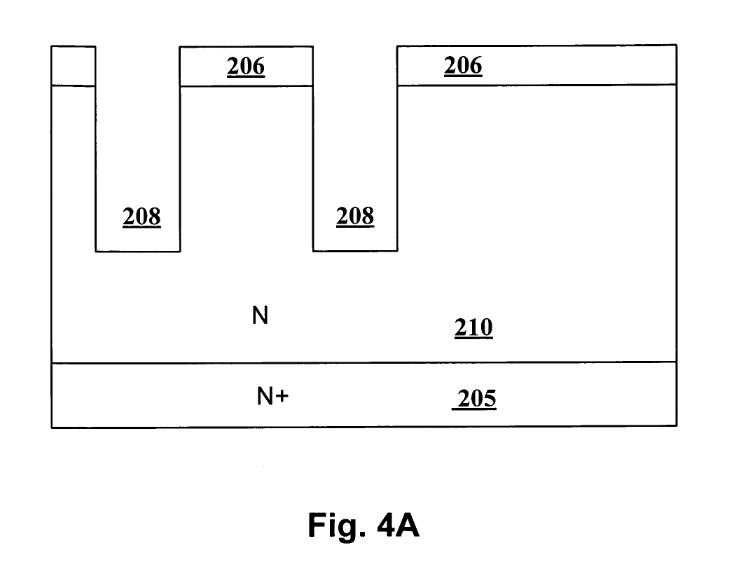

Please refer to FIG. 3 for preferred an embodiment of this invention where a metal oxide semiconductor field effect transistor (MOSFET) device 100 is formed on a Phosphorus N+ substrate 105 formed with an N epitaxial layer 110. The MOSFET 100 includes a trenched gate 120 disposed in a trench with a gate insulation layer formed over the walls of the trench. A body region 125 that is doped with a dopant of second conductivity type, e.g., P-type dopant, extends between the trenched gates 120.

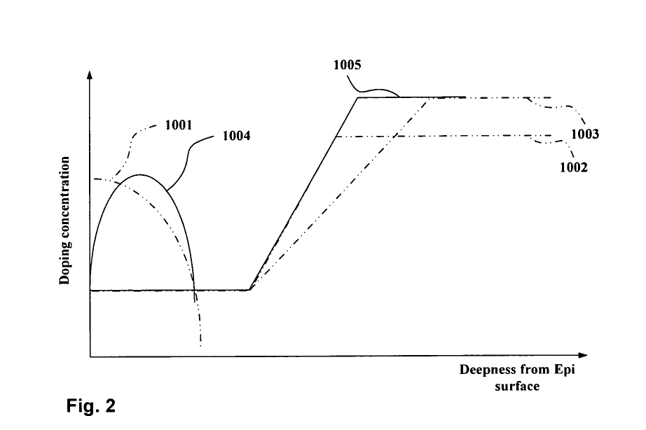

For the purpose of reduce the drain-source resistance significantly, the substrate of this invention is Phosphorus substrate as mentioned which has a resistivity lower than 2.0 mohm-cm. On the other hand, P-body region is implemented by medium or high energy (100˜400 KeV) Ion Implantation and followed by Anneal at 1000˜1100 C to form a retrograded P-body/N-Epi junction (1004 in FIG. 2) with thinner Epi. And incorporated with the Phosphorus substrate (1005 in FIG. 2), the impact of drift resistance and substrate resistance encountered in prior art is also reduced.

Referring to FIGS. 2 and 3 again, the retrograded P-body regions in FIG. 2 and 125 in FIG. 3 encompassing a source region 130 doped with the dopant of the first conductivity, e.g., N+ dopant. The source regions 130 are formed near the top surface of the epitaxial layer surrounding the trenched gates 120. The top surface of the semiconductor substrate extending over the top of the trenched gate, the P body region 125 and the source regions 130 are covered with a insulation layer which comprises a first oxide layer 135 and a second oxide layer 140. The first oxide layer 135 can be formed through a deposition of a undoped SRO (Silicon Rich oxide with refractive index greater than 1.46) layer, and the second oxide layer 140 can be formed through a deposition of a glass layer, which can be selected from BPSG (Borophosphosilicate Glass) or PSG (Phosphosilicate Glass).

In order to improve the source contact to the source regions 130, a plurality of trenched source contact filled with a tungsten plug 145 surrounded by an alternative barrier layer 150, which is formed through deposition of Ti/TiN or Co/TiN, for Co has better metal step coverage than Ti for contact CD smaller than 0.25 um, and is widely used in industry. The usage of Ti/TiN/W or Co/TiN/W plug in sloped trench source contact further reduces drain-source resistance, as well as the channel resistance as result of increase in cell density due to cell pitch reduction. On the other hand, the stepwise structure of the barrier layer will improve the ohmic contact due to larger contact area between W plug and Ti (or Ti/TiN)/Thick metal. The contact trenches are opened through the NSG and BPSG OR PSG protective layers 135 and 140 to contact the source regions 130 and the P-body 125. Then a conductive layer 155 of Ti or Ti/TiN is formed over the top surface to reduce contact resistance between the thick front metal 160 and the tungsten plug 145. The front metal layer 160 is formed with aluminum, aluminum-cooper, AlCuSi, or Ni/Ag, Al/NiAg, AlCu/NiAu or AlCuSi/NiAu as a wire-bonding layer. The tungsten plug 145 surrounded by the barrier layer 150 as shown in FIG. 3 are opened with a slope relative to the regular perpendicular direction for contacting a P+ doped region 128 surrounding the source-body trenched contact. The P+ doped region 128 is formed to enhance avalanche current before triggering parasitic N+PN bipolar, i.e., the N+ source 130 with a P-body 125 and the N-epitaxial layer 110. A high avalanche current is an important parameter for application in DC/DC conversion devices. A parasitic N+PN bipolar will be turned on when the avalanche current Iav*Rp is equal to 0.7 volts where Iav is the avalanche current and Rp is the resistance underneath the N+ source regions between the trenched gate 120 and the trenched source contact 145. For the purpose of not triggering the parasitic bipolar N+PN, by reducing the resistance Rp with a P+ doped region surrounding the trenched source-body contact 145 as implemented in this invention, a higher value of avalanche current Iav is achievable to obtain better performance in a DC/DC conversion device. As will be further described and discussed below of the processing steps in forming the MOSFET as shown, the sloped trenches allow the formation of heavily doped P+ doped regions 128 along both the trench sidewalls and the bottom through zero degree ion implantation of boron or BF2. The heavily doped P+ regions 128 provide good ohmic contact between the Ti/TiN/W source body contact 145 and the P-body to reduce the parasitic resistance Rp underneath the N+ source regions 130. The structure enable an avalanche to occur near the bottom-corner of the trenched gate 120 and the avalanche current flows through the P-body 125 then collected by the Ti/TiN/W trenched source-body contact 145. The reduced body resistance Rp determined by the space between trench gate and contact edge as discussed above enhances the avalanche current without triggering the turning on of a parasitic N+PN bipolar parasitically formed between the N+ source 130 with a P-body 125 and the N-epitaxial layer 110. The optimum contact space from trench gate is 0.1˜0.3 um. If the space is smaller than 0.1 um, the Rds is increased as result of P+ touching to cannel region, causing higher threshold voltage Vth. On the other hand, if the space greater than 0.3 um, the avalanche capability is degraded due to high Rp.

Referring to FIG. 2 again, a curve 1004 on the left shows the characteristic of P-body implanted with medium or high energy Ion Implantation and followed by anneal at 1000˜1100° C. to form a retrograded P-body region. Another curve 1005 on the right represent N+ out diffusion due to P-body anneal. It indicates that same P-body/N-Epi junction can be formed with thinner Epi. And the impact of drift resistance encountered in prior is reduced.

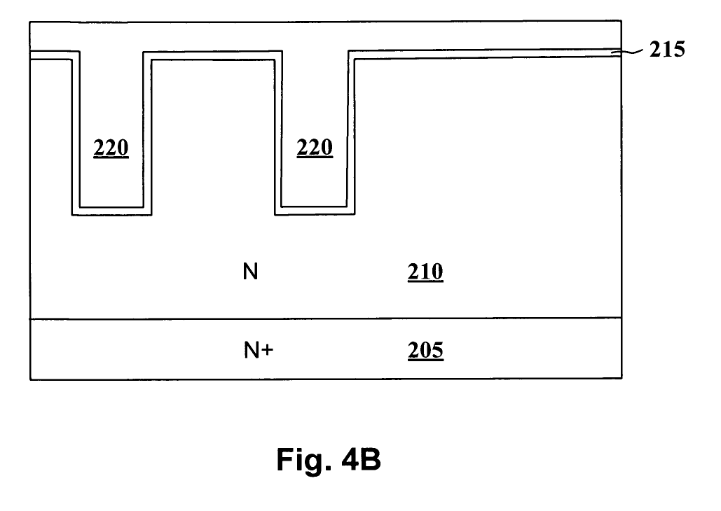

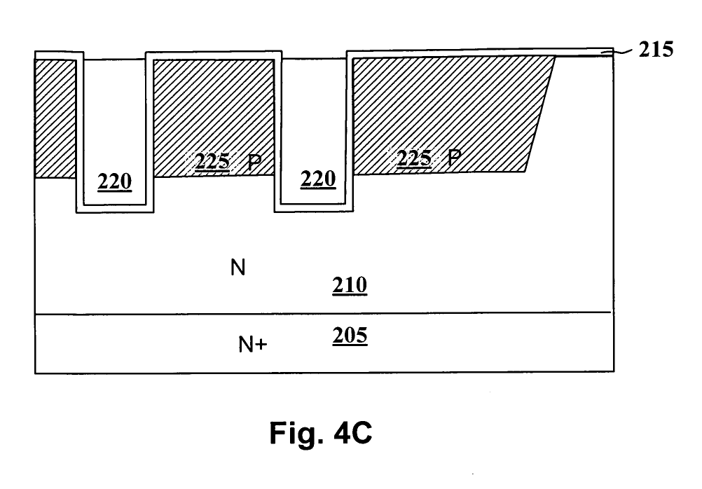

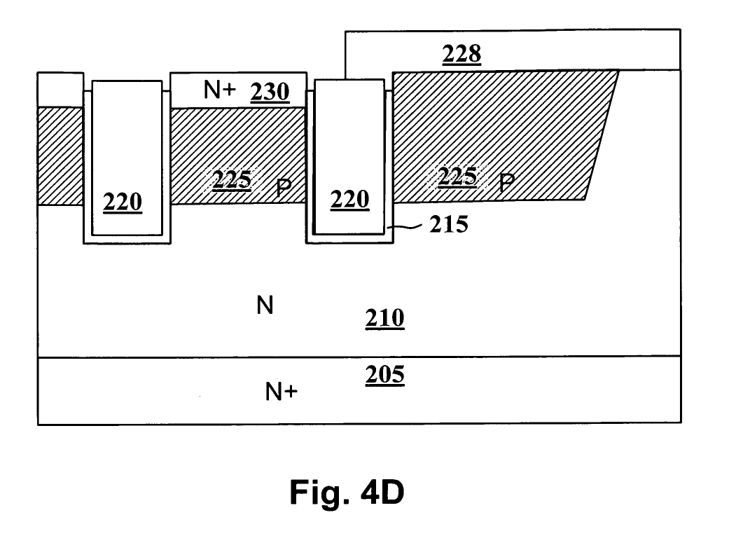

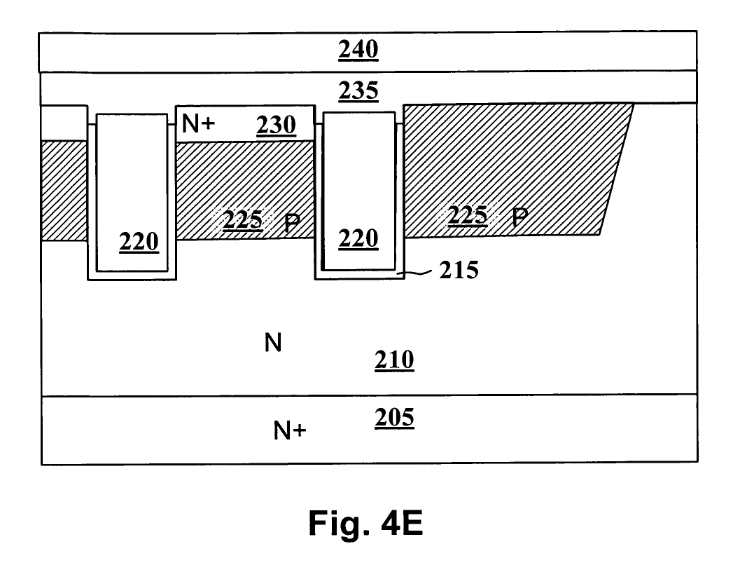

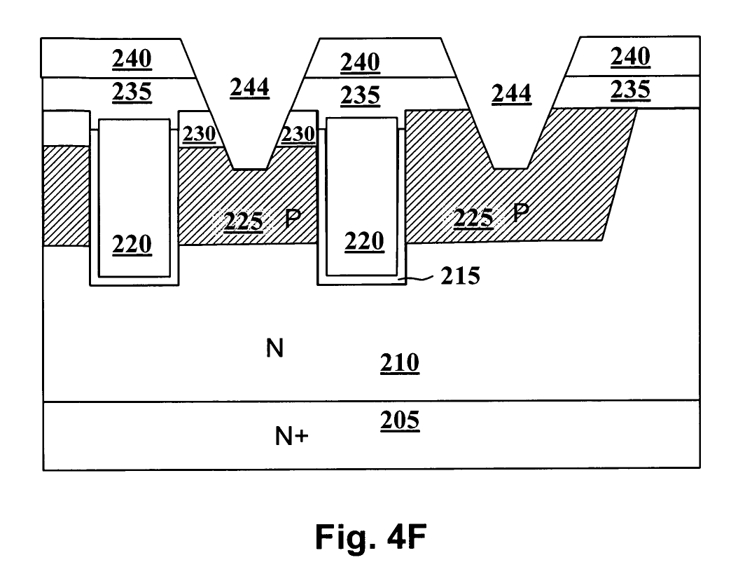

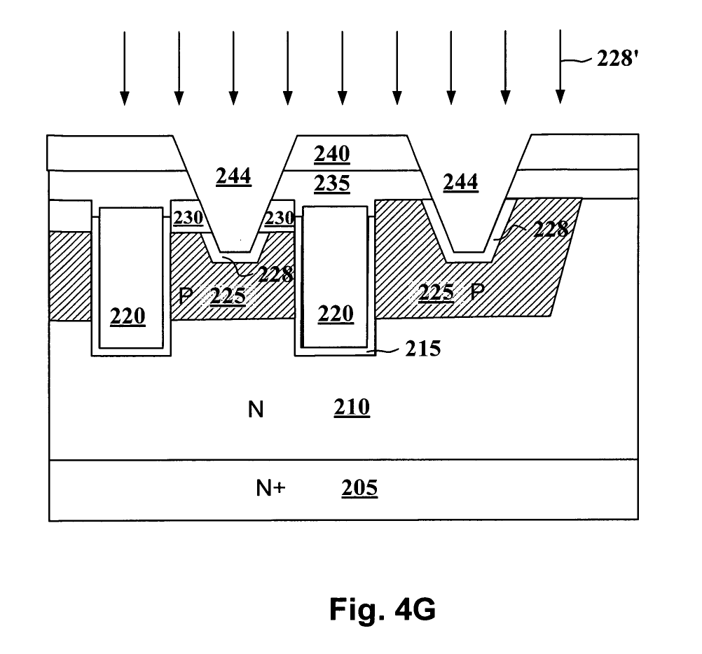

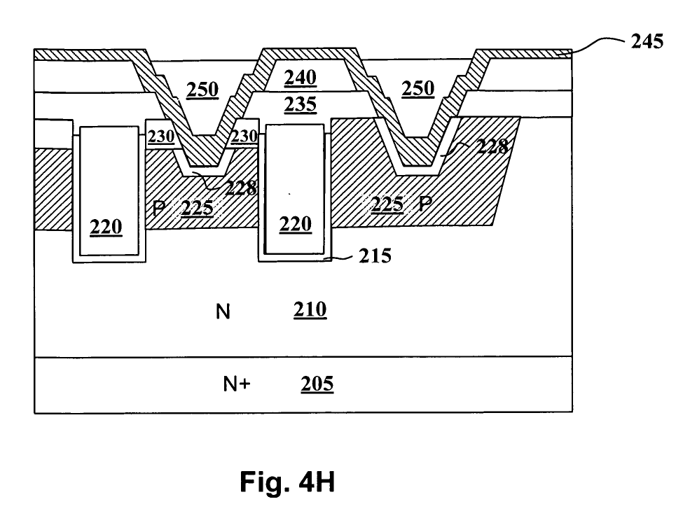

Referring to FIG. 4A to 4I for a serial of side cross sectional views to illustrate the fabrication steps of a MOSFET device as that shown in FIG. 3. In FIG. 4A, a photoresist 206 is applied to open a plurality of trenches 208 in an epitaxial layer 210 supported on a Phosphorus substrate 205. In FIG. 4B, the said trenches 208 are oxidized with a sacrificial oxide to remove the plasma damaged silicon layer during the process of opening the trench. An oxidation process is then performed to form an oxide layer 215 as gate oxide covering the walls and the bottoms of the trenches 208, respectively. Then a polysilicon layer 220 is deposited to fill the trenches 208 and covering the top surface of the epitaxial layer 210. In FIG. 4C, after a P-body implant with a P-type dopant, the polysilicon layer 220 is etched back. Then an elevated temperature (1000˜1100° C.) is applied to diffuse the P-body 225 into the epitaxial layer 210 using medium or high energy (which can be between 100˜400 KeV) Ion Implantation. In FIG. 4D, a source mask 228 is applied to define a zone for a source implant with a N-type dopant. Then an elevated temperature (which can be between 800˜1000° C.) is applied to diffusion the source region 230. In FIG. 4E, a first oxide layer 235 and a second oxide layer 240 are deposited on the top surface of the epitaxial layer 210. The first oxide layer 235 can be formed through a deposition of a undoped SRO (Silicon Rich oxide with refractive index greater than 1.46) layer, and the second oxide layer 240 can be formed through a deposition of a glass layer, which can be selected from BPSG (Borophosphosilicate Glass) or PSG (Phosphosilicate Glass).

In FIG. 4F, a contact mask (not shown) is applied to carry out a contact etch to open a plurality of contact openings which are defined as a plurality of source-body contact trenches 244 by applying an dry oxide etching through the BPSG or PSG layer 240 and SRO layer 235 followed by a silicon etch to open the source-body contact trenches 244 further deeper into the source regions 230 and the body regions 225. The MOSFET device thus includes the source-body contact trench 244 that has an oxide layers, e.g., the BPSG OR PSG layer 240 and SRO layer 235. The source-body contact trench 244 further includes a silicon trench formed by applying a silicon etching following the oxide etching. The oxide etching and silicon etching may be a dry oxide and silicon etching whereby a critical dimension (CD) of the each source-body contact trench 244 is better controlled. For the purpose of opening the source-body contact trenches 244, different etching processes are available. The various slope and vertical contact trench profiles for the contact trenches 244 are achieved by using different gas ratios of C4F8(or C3F6)/CO/O2/Ar plasma for dry oxide etching and CF4(or HBr)/O2/C12 plasma for dry silicon etching.

In FIG. 4G, a BF2 implant with P+ ions 228′ is first performed to form the P+ doped region 228 to surround lower parts of the trenches 224 and to form a body-resistance-reduction region which can reduce the resistance underneath the N+ source regions 230 between the trenched gate 220 and the trenched source contact 250. The implantation is carried out along a direction of zero degree relative to a perpendicular direction relative to the substrate top surface because the sloped sidewalls of the contact trenches 224. In FIG. 4H, a wet oxide etching is applied to form stepwise structure for better ohmic contact, then a barrier layer 245, which can be selected from a composited layer of Ti and TiN or a composited layer of Co and TiN, is deposited onto the top surface of the source-body contact trenches 244 and the second oxide layer 240. Thereafter, a tungsten layer 250 is deposited on the top surface of the barrier layer 245, and the barrier layer 245 and the tungsten layer 250 fill in the source-body contact trenches 244 to function as a source and body contact plug. Then a tungsten etching is carried out to etch back the tungsten layer 250. In FIG. 4I, a low resistance metal layer 255 is deposited over the top surface. The low resistance metal layer is composed of Ti or Ti/TiN to assure good ohmic contact between the tungsten plug 250 and the low resistance metal layer 255 is established. Then a thick front metal 260 is deposited over the top surface. The thick front metal 260 may be Al or AlCu or AlCuSi or Ni/Ag or Al/NiAu or AlCu/NiAu or AlCuSi/NiAu. And then a metal mask is applied to carry out a metal layer followed by a metal etched back.

Besides, a back metal layer (not shows in the figures) formed on a bottom surface of the MOSFET device 100 to be corresponding to the drain region of the MOSFET.

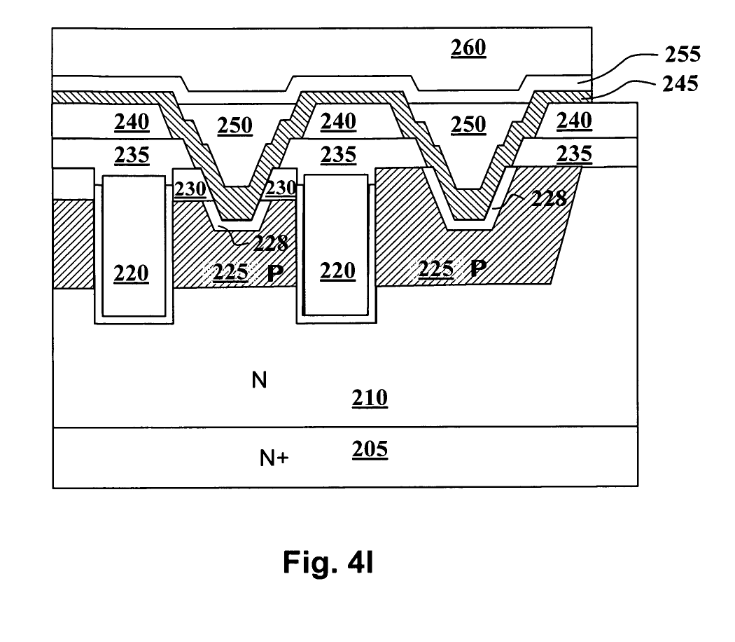

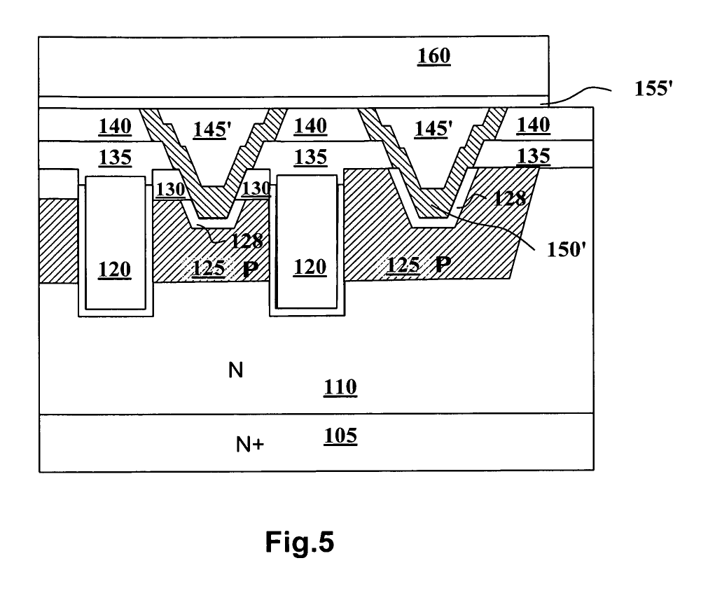

Referring to FIGS. 3 and 5, the FIG. 5 shows another embodiment of this invention which is different from no barrier layer 150 (Ti or Ti/TiN) etching off in FIG. 3. In the FIG. 5, after a plurality of trenched source contact filled with a tungsten plug 145′ surrounded by a barrier layer 150′, the tungsten plug 145′ and the barrier layer 150′ are etched back to form a plane surface. Then, a low resistance metal layer 155′ is formed over the top surface to contact the tungsten plug 145′ and the barrier layer 150′. Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET with on-resistance reduction comprising a trenched gate surrounded by a source region encompassed in a body region above a drain region disposed on a bottom surface of a substrate, wherein the said MOSFET further comprising:
an epitaxial layer corresponding to the drain region of the MOSFET;
an insulation layer covered over the top of the trenched gate, the body region and the source region;
a plurality of source-body contact trenches opened relative to a top surface into said source and body regions and each of the source-body contact trenches is filled with a contact metal plug as a source-body contact;
a low resistance metal layer is deposited on top of said contact metal plug;
a front metal layer formed on a top surface of the MOSFET and connected to said low resistance metal layer;
a back metal layer formed on a bottom surface of the MOSFET;
wherein a low-resistivity phosphorus substrate and retrograded P-body formed by ion implantation with medium or high energy or combination of both energies to reduce Rds contribution from substrate and drift region.

2. The MOSFET of claim 1, wherein the source-body contact trenches are opened with sloped sidewalls relative to a top surface through said source region and into said body region.

3. The MOSFET of claim 1 wherein the contact metal plug further comprising a barrier layer surrounding the contact metal plug.

4. The MOSFET of claim 1 wherein the contact metal plug is selected from tungsten, and the barrier layer is selected from a composited layer of Ti and TiN or a composited layer of Co and TiN.

5. The MOSFET of claim 1 wherein the sloped sidewalls of the source-body contact trenches are sloped with 60 to 90 degree respect to the epitaxial layer surface.

6. The MOSFET of claim 1, wherein the insulation layer comprises a first oxide layer, which can be formed through a deposition of a undoped SRO layer with refractive index greater than 1.46, and a second oxide layer, which can be formed through a deposition of a doped glass layer such as BPSG or PSG.

7. The MOSFET of claim 1 wherein the source-body contact trenches are stepwise structure.

8. The MOSFET of claim 1 wherein the source-body contact trenches are formed by a dry oxide etching, a dry silicon etching, and a wet oxide etching in sequence.

9. The MOSFET of claim 1, wherein the each source-body contact trench further comprises a body-resistance-reduction region surrounding both sidewalls and bottom portions of the each source-body contact trench to reduce the resistance underneath the source regions between the trenched gate and the source-body contact. The body-resistance-reduction region has a dopant ranging from 5E14˜5E15 cm−2 of a same conductivity type as a body dopant doped in said body regions.

10. The MOSFET of claim 1, wherein the Phosphorus substrate with resistivity lower than 2.0 mohm-cm.

11. The MOSFET of claim 1, wherein the P-body Ion Implantation energy rangers from 100 to 400 KeV.

12. The MOSFET of claim 1, wherein the space between the trenched gate and the nearest trenched source contact edge along the epitaxial layer surface ranging from 0.1 to 0.3 um for device ruggedness assurance without impacting Rds.

13. The MOSFET of claim 1, wherein the front metal layer is selected from one of Al, AlCu and AlCuSi for wire bonding.

14. The MOSFET of claim 1, wherein the front metal layer is selected from one of Al/NiAu, AlCu/NiAu, AlCuSi/NiAu, Ni/Ag and NiAu for wireless bonding.

15. The MOSFET of claim 1, wherein the low resistance metal layer is Ti or Ti/TiN.

16. A method for manufacturing a trench MOSFET comprising the steps of:
growing an epitaxial layer upon a phosphorus substrate, wherein said epitaxial layer is doped with a first type dopant, eg., N type dopant;
forming a trench mask with open and closed areas on the surface of said epitaxial layer;
removing semiconductor material from exposed areas of said trench mask to form a plurality of gate trenches;
depositing a sacrificial oxide layer onto the surface of said trenches to remove the plasma damage introduced during opening said trenches;
removing said sacrificial oxide and said trench mask;
forming gate oxide on the surface of said epitaxial layer and along the sidewalls and the bottoms of said trenches;
depositing a layer of N+ doped poly onto said gate oxide and into said trenches;
etching back said N+ doped poly from the surface of said gate oxide and leaving enough N+ doped poly in said trenches to serve as trench gates;
implanting said epitaxial layer with a second type dopant to form P body regions;
forming a layer of source mask to define the source regions;
implanting said epitaxial layer with a first type dopant to form source regions near the surface of said P body regions in the open regions of said source mask;
removing said source mask and depositing a layer of SRO on the surface of whole device;
depositing a layer of BPSG on the surface of said SRO layer;
forming a contact mask with open and closed areas on the surface of said BPSG layer;
removing oxide material and semiconductor material from areas exposed by the open areas of said contact mask to form contact trenches;
implanting BF2 ion over the entire surface to form the P+ areas around the bottom of said contact trenches;
forming stepwise structure on the sidewalls of said contact trenches for better ohmic contact; depositing a layer of Ti/TiN or Co/TiN on the surface of said BPSG layer and along the sidewalls and the bottoms of said contact trenches;
depositing W material in said contact trenches and onto said Ti/TiN or Co/TiN layer and etching back W to leave it only in said contact trenches to form contact material;
etching back Ti/TiN or Co/TiN from surface of said BPSG layer;
depositing a layer of Ti on the entire surface;
depositing a thick layer of front metal onto said Ti layer;
forming a layer of metal mask onto said front metal layer and exposed to pattern said metal mask into source metal and gate metal;
removing metal material from exposed area of said metal mask;

17. The method of claim 16 wherein forming said gate trenches comprises etching said epitaxial layer by dry silicon etching according to the open areas of said trench mask;

18. The method of claim 16 wherein forming said P body regions comprises a step of diffusion to achieve a certain depth after P body implantation step;

19. The method of claim 16 wherein forming said source regions comprises a step of diffusion to achieve a certain depth after source implantation step;

20. The method of claim 16 wherein forming said contact trenches comprises etching through said BPSG layer and said SRO layer according to the open areas of said contact mask;

21. The method of claim 16 wherein forming said contact trenches comprises etching penetrating said source regions by dry silicon etching according to open areas of said contact mask;

22. The method of claim 16, wherein forming said contact trenches comprises etching into said P body regions by dry silicon etching according to open areas of said contact mask;

23. The method of claim 16, wherein etching penetrating said source regions and into said P body regions according to open areas of said contact mask comprises making a symmetrical slope sidewalls and plane bottoms of said contact trenches;

24. The method of claim 16 wherein forming said stepwise structure on sidewalls of said contact trenches comprises etching said SRO layer and said BPSG layer using Wet Oxide Etch method;

25. The method of claim 16 wherein depositing a thick layer of front metal comprises depositing a thick layer of Al or AlCu or AlCuSi or Ni/Ag or Al/NiAu or AlCu/NiAu or AlCuSi/NiAu onto said Ti layer;

26. The method of claim 16 wherein forming said front metal layer comprises etching said front metal according to the exposed areas of said metal mask.
